(19) United States
(12) Patent Application Publication
(10) Pub. No.: US 2007/0023082 A1
(43) Pub. Date: Feb. 1, 2007

(54) Compositionally-graded back contact photovoltaic devices and methods of fabricating such devices

(76) Inventors: Venkatesan Manivannan, Rexford, NY (US); James N. Johnson, Scotia, NY (US)

Correspondence Address: Patrick S. Yoder;FLETCHER YODER, P.O. Box 692289, Houston, TX, 77269-2289, US

(21) Appl. No.: 11/374,368

(22) Filed: Mar. 13, 2006

Related U.S. Application Data
(60) Provisional application No. 60/704,181, filed on Jul. 28, 2005.

(51) Int. Cl. H01L 31/00

(52) U.S. Cl. 136/258

(57) ABSTRACT

A semiconductor structure is described, including a semiconductor substrate and an amorphous semiconductor layer disposed on the front side of the semiconductor substrate, wherein the amorphous semiconductor layer is compositionally graded through its depth, from substantially intrinsic at the interface with the substrate, to substantially conductive at the opposite side. A plurality of front contacts are disposed on the backside of the substrate, and a plurality of vias formed through the substrate, wherein the plurality of vias are filled with a conductive material configured to electrically couple the amorphous semiconductor layer to one of the plurality of front contacts. Back contacts are disposed such that they are interdigitated with the front contacts. Related methods are also described.

### CROSS-REFERENCE TO RELATED APPLICATIONS

Non-Provisional Application Ser. No. 11/263,159, filed on Oct. 31, 2005, which claims priority to a provisional application (60/704,181), filed on Jul. 28, 2005, is hereby incorporated by reference.

### BACKGROUND OF THE INVENTION

This invention relates generally to the field of semiconductor devices which include a heterojunction, such as a photovoltaic device.

Devices which rely on the presence of a heterojunction are well-known in the art. As used herein, a “heterojunction” is usually formed by contact between a layer or region of one conductivity type (e.g., p-type) with a layer or region of an opposite conductivity type (e.g., n-type), thereby forming a “p-n” junction. Examples of these devices include thin film transistors, bipolar transistors, and photovoltaic devices (i.e., solar cells).

Photovoltaic devices convert radiation, such as solar, incandescent, or fluorescent radiation, into electrical energy. Sunlight is the typical source of radiation for most devices. The conversion to electrical energy is achieved by the well-known “photovoltaic effect.” According to this phenomenon, radiation striking a photovoltaic device enters the absorber region of the device, generating pairs of electrons and holes, which are sometimes collectively referred to as photo-generated charge carriers. The electrons and holes diffuse in the absorber region, and are collected by the electric field at the heterojunction.

The increasing interest in solar cells as a reliable form of clean, renewable energy has prompted great efforts in increasing the performance of the cells. One way to improve cell performance is to improve the photoelectric conversion efficiency of the device. Conversion efficiency is usually measured as the amount of electrical current generated by the device, as a proportion of the light energy which contacts its active surface. Typical photovoltaic devices only exhibit a conversion efficiency of about 15% or less. With this in mind, even small increases in photoelectric conversion efficiency, e.g., 1% or less, represent very significant advances in photovoltaic technology.

In order to improve photovoltaic conversion efficiency, various conditions which contribute to the reduction in cell efficiency can be minimized. Two such deleterious effects that have been attributed to the reduction in overall cell efficiency include charge carrier recombination and shadowing losses. Thus, improvements in one or both of these areas will generally improve the photovoltaic conversion efficiency, as described further below.

The performance of photovoltaic devices depends in large part on the composition and microstructure of each semiconductor layer. For example, defect states which result from structural imperfections or impurity atoms may reside on the surface or within the bulk of monocrystalline semiconductor layers and may contribute to charge carrier recombination. Moreover, polycrystalline semiconductor materials may contain randomly-oriented grains, with grain boundaries which induce a large number of bulk and surface defect states.

The presence of various defects of this type can be the source of deleterious effects in the photovoltaic device. For example, many of the charge carriers recombine at the defect sites near the heterojunction, instead of continuing on their intended pathway to one or more collection electrodes. Thus, they become lost as current carriers. Recombination of the charge carriers is one of the primary contributors to decreased photoelectric conversion efficiency.

The negative effects of surface defects can be minimized to some degree by passivation techniques. For example, a layer of intrinsic (i.e., undoped) amorphous semiconductor material can be formed on the surface of the substrate. The presence of this intrinsic layer decreases the recombination of charge carriers at the substrate surface, and thereby improves the performance of the photovoltaic device.

While the introduction of an intrinsic layer may address the recombination problem to some degree, there are some considerable drawbacks remaining. For example, the presence of the intrinsic layer, while beneficial in some ways, results in the formation of yet another interface, i.e., between the intrinsic layer and the overlying amorphous layer. This new interface is yet another site for impurities and spurious contaminants to become trapped and to accumulate, and possibly cause additional recombination of the charge carriers. For example, interruptions between the deposition steps during fabrication of a multilayer structure can provide unwelcome opportunities for the entry of the contaminants. Moreover, abrupt band bending at the interface, due to a change in conductivity, and/or variations in band gap, can lead to a high density of interface states, which is another possible source of recombination.

In addition to the design considerations associated with the issue of charge carrier recombination, shadowing effects, which also degrade device performance, should also be considered. Shadowing effects generally refer to the shadowing created by the presence of the metal contacts on the front surface of the photovoltaic device. As will be appreciated, the front contacts generally serve as one of the conducting electrodes of the device. Disadvantageously, by placing contacts on the front surface of the device, the incident light rays are blocked at the contact areas. The light blockage is generally referred to as “shading” or “shadowing.” Shadowing prevents the areas of the underlying active materials from receiving incident radiation, thereby reducing the generation of charge carriers. Obviously, a reduction in charge carriers can reduce the efficiency of the photovoltaic device.

With some of these concerns in mind, improved photovoltaic devices would be welcome in the art. The devices should minimize the problem of charge-carrier recombination at various interface regions between semiconductor layers, as well as the problems associated with the shadowing created by the front side contacts. Moreover, the devices should exhibit electrical properties which ensure good photovoltaic performance, e.g., photoelectric conversion efficiency. Furthermore, the devices should be capable of being made efficiently and economically. The fabrication of the devices should eliminate deposition steps which would allow the entry of excessive levels of impurities and other defects.

### BRIEF DESCRIPTION OF THE INVENTION

In accordance with one embodiment of the present invention, there is provided a semiconductor structure. The semiconductor structure comprises a semiconductor substrate, wherein the substrate comprises a front side configured to receive incident light radiation, and a backside. The front and back surfaces of the semiconductor substrate may optionally be textured to enhance light trapping. The semiconductor structure further comprises an amorphous semiconductor layer disposed on the front side of the semiconductor substrate, wherein the amorphous semiconductor layer is compositionally graded through its depth, from substantially intrinsic at the interface with the substrate, to substantially conductive at the opposite side. The semiconductor structure also comprises a plurality of front contacts disposed on the backside of the substrate. The semiconductor structure further comprises a plurality of vias formed through the substrate, wherein each of the plurality of vias are filled with a conductive material configured to electrically couple the amorphous semiconductor layer to one of the plurality of front contacts.

In accordance with another embodiment of the present invention, there is provided a semiconductor structure comprising a semiconductor substrate comprising a front side configured to receive incident light radiation, and a backside. The semiconductor structure further comprises a first amorphous semiconductor layer disposed on the front side of the semiconductor substrate, wherein the first amorphous semiconductor layer is compositionally graded through its depth, from substantially intrinsic at the interface with the substrate, to substantially conductive at the opposite side. The semiconductor structure further comprises a transparent electrode layer disposed on the first amorphous semiconductor layer. The semiconductor structure further comprises a second amorphous semiconductor layer disposed on a first plurality of areas on the back side of the semiconductor substrate. The semiconductor structure further comprises a plurality of front contacts disposed on the second amorphous semiconductor layer. The semiconductor structure further comprises a plurality of vias formed through the substrate, wherein the plurality of vias are filled with a conductive material configured to electrically couple the transparent electrode layer to one of the plurality of front contacts. The semiconductor structure further comprises a third amorphous semiconductor layer disposed on a second plurality of areas on the back side of the semiconductor substrate, wherein the third amorphous semiconductor layer is compositionally graded through its depth, from substantially intrinsic at the interface with the substrate, to substantially conductive at the opposite side. The semiconductor structure further comprises a plurality of back contacts disposed on the third amorphous semiconductor layer.

A method for making a photovoltaic device, comprising disposing a first amorphous semiconductor layer on a front side of a semiconductor substrate, wherein the first amorphous semiconductor layer is compositionally graded through its depth, from substantially intrinsic at the interface with the substrate, to substantially conductive at the opposite side. The method further comprises disposing a second amorphous semiconductor layer on a first plurality of areas on a backside of the semiconductor substrate. The method further comprises disposing a third amorphous semiconductor layer on a second plurality of areas on the backside of the semiconductor substrate, wherein the third amorphous semiconductor layer is compositionally graded through its depth, from substantially intrinsic at the interface with the substrate, to substantially conductive at the opposite side. The method further comprises forming a plurality of vias through the substrate. The method further comprises filling each of the plurality of vias with a conductive material. The method further comprises forming a plurality of front contacts on the second amorphous semiconductor layer. The method further comprises forming a plurality of back contacts on the third amorphous semiconductor layer.

### BRIEF DESCRIPTION OF THE DRAWINGS

Advantages and features of the invention may become apparent upon reading the following detailed description and upon reference to the drawings in which:

FIG. 1 is a schematic cross-section which depicts the structure of a photovoltaic device according to one embodiment of the present invention;

FIG. 2 is a partially exploded cutaway diagrammatic plan view of the structure of FIG. 1;

FIG. 3 is a flow chart of an exemplary process for fabricating the structure of FIG. 1; and

FIG. 4 is a schematic cross-section which depicts the structure of a photovoltaic device according to another embodiment of the present invention;

### DETAILED DESCRIPTION OF THE INVENTION

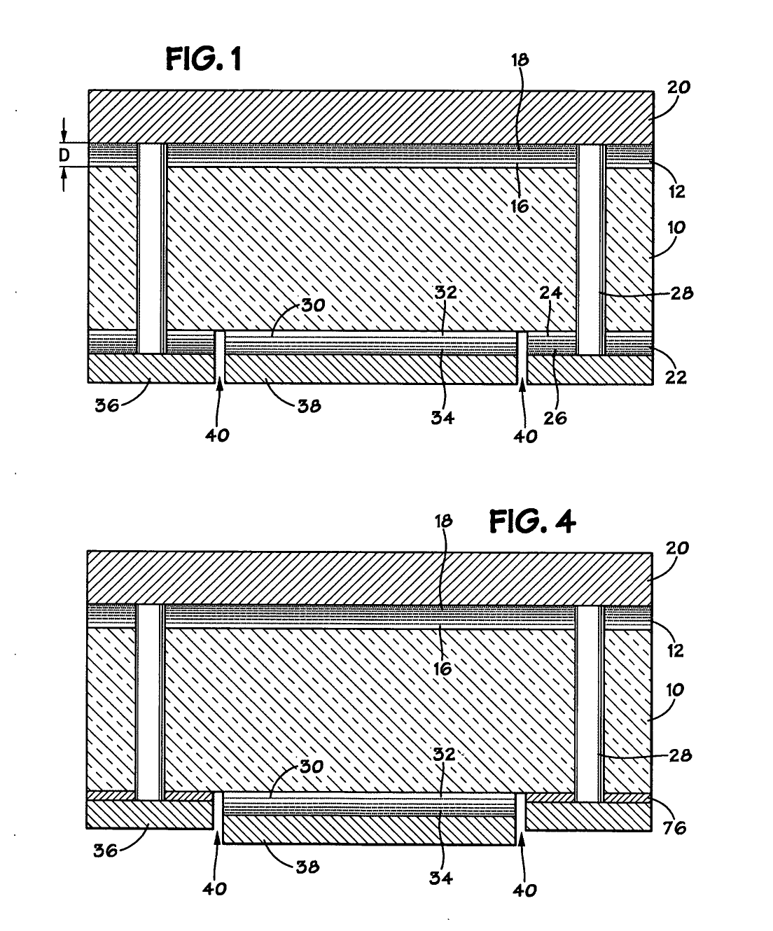

Turning now to the figures and referring initially to FIG. 1, a substrate 10 configured in accordance with embodiments of the present invention is illustrated. A variety of substrates can be used for most embodiments of this invention. For example, with reference to FIG. 1, the substrate 10 can be monocrystalline or polycrystalline. The front and back surfaces of the semiconductor substrate may optionally be textured to enhance light trapping. Moreover, the substrate material can be n-type or p-type, depending in part on the electrical requirements for the photovoltaic device. Those skilled in the art are familiar with the details regarding all of these types of silicon substrates. For illustrative purposes, the substrate 10 comprises an n-type silicon substrate.

The substrate is usually subjected to conventional treatment steps, prior to deposition of the other semiconductor layers. For example, the substrate can be cleaned and placed in a vacuum chamber (e.g., a plasma reaction chamber, as described below). The chamber can then be heated to temperatures sufficient to remove any moisture on or within the substrate. Usually, a temperature in the range of about 120-240° C. is sufficient to remove any moisture. Sometimes, hydrogen gas is then introduced into the chamber, and the substrate is exposed to a plasma discharge, for additional surface-cleaning. However, many variations on cleaning and pretreatment steps are possible. Usually, these steps are carried out in the chamber used for additional fabrication of the device.

The various semiconductor layers formed over the substrate are usually (though not always) applied by plasma deposition. Many different types of plasma deposition are possible. Non-limiting examples include chemical vapor deposition (CVD); vacuum plasma spray (VPS); low pressure plasma spray (LPPS), plasma-enhanced chemical-vapor deposition (PECVD), radio-frequency plasma-enhanced chemical-vapor deposition (RFPECVD); expanding thermal-plasma chemical-vapor deposition (ETPCVD); electron-cyclotron-resonance plasma-enhanced chemical-vapor deposition (ECRPECVD), inductively coupled plasma-enhanced chemical-vapor deposition (ICPECVD), and air plasma spray (APS). Sputtering techniques could also be used, e.g., reactive sputtering. Moreover, combinations of any of these techniques might also be employed. Those skilled in the art are familiar with the general operating details for all of these deposition techniques. In some preferred embodiments, the various semiconductor layers are formed by a PECVD process.

As mentioned previously, an amorphous semiconductor layer 12 is formed on a top surface 14 of semiconductor substrate 10. Semiconductor layer 12 is compositionally graded, in terms of dopant concentration. In general, the dopant concentration is substantially zero at the interface with the substrate, i.e., portion 16 in FIG. 1. On the opposite side of layer 12, i.e., portion 18, the dopant concentration is at a maximum, in terms of semiconductor conductivity objectives.

As used herein, “compositionally-graded” is meant to describe a gradual change (i.e., a “gradation”) in dopant concentration as a function of the depth (“D”) of an amorphous semiconductor layer, such as the semiconductor layer 12. In some embodiments, the gradation is substantially continuous, but this does not always have to be the case. For example, the rate-of-change in concentration may itself vary through the depth, increasing slightly in some regions, and decreasing slightly in others. However, as used herein, the overall gradation is always characterized as a decrease in dopant concentration in the direction toward substrate 10. Moreover, in some instances, the dopant concentration may remain constant for some portion of the depth, although that portion would generally be very small. Any and all of these variations in gradations are meant to be encompassed by the term “graded”. The specific dopant concentration profile for a given semiconductor layer will depend on various factors, e.g., type of dopant, electrical requirements for the semiconductor device, the deposition technique for the amorphous layer, as well as its microstructure and thickness.

The dopant concentration is substantially zero at the interface with the substrate, regardless of the particular dopant profile. Thus, an intrinsic region is present at the interface, functioning to prevent recombination of the charge-carriers. At the opposite, the upper surface of amorphous layer 12, region 18, is substantially conductive. The specific dopant concentration in that region will depend on the particular requirements for the semiconductor device. As a non-limiting example in the case of a polycrystalline or single crystalline silicon substrate, region 18 will often have a concentration of dopant in the range of about 1×10¹⁶ cm⁻³ to about 1×10²¹ cm⁻³.

The thickness of graded amorphous layer 12 will also depend on various factors, such as the type of dopant employed, the conductivity-type of the substrate, the grading profile, the dopant concentration in region 18, and the optical band gap of layer 12. Usually, the thickness of layer 12 is less than or equal to about 250 Angstroms. In some specific embodiments, graded layer 12 has a thickness in the range of about 30 Angstroms to about 180 Angstroms. The most appropriate thickness in a given situation can be determined without undue effort, e.g., by taking measurements related to the photoelectric conversion efficiency of the device, as well as its open circuit voltage (V_{OC}) and short circuit current (I_{SC}).

The compositional-grading of semiconductor layer 12 can be carried out by various techniques. Usually, grading is accomplished by adjusting the dopant levels during plasma deposition. In a typical embodiment, a silicon precursor gas such as silane (SiH₄) is introduced into the vacuum chamber in which the substrate is situated. A diluting gas such as hydrogen may also be introduced with the silicon precursor gas. Flow rates for the precursor gas can vary considerably, but are typically in the range of about 10 sccm to about 60 sccm. During the initial stages of deposition, no dopant precursors are present. Therefore, region 16 is substantially intrinsic (“undoped”), as mentioned above, thus serving to passivate the surface of substrate 10.

As the deposition process continues, a dopant precursor is added to the plasma mixture. Choice of a precursor will of course depend on the selected dopant, e.g., n-type dopants such as phosphorus (P), arsenic (As), and antimony (Sb); or p-type dopants such as boron (B). Several non-limiting examples of dopant compounds can be provided: diborane gas (B₂H₆) for the p-type dopant, or phosphine (PH₃) for the n-type dopant. The dopant gasses may be in pure form, or they may be diluted with a carrier gas, such as argon, hydrogen, or helium.

The addition of the dopant gas is carefully controlled, to provide the desired doping profile. Those skilled in the art are familiar with gas metering equipment, e.g., mass flow controllers, which can be used to carry out this task. The feed rate for the dopant gas will be selected to substantially match the gradation scheme described above. Thus, in very general terms, the feed rate of the dopant gas will gradually increase during the deposition process. However, many specific changes in feed rate can be programmed into the deposition scheme. Maximum flow rates at the conclusion of this step of the process result in the formation of substantially-conductive region 18, as mentioned previously. Region 18 has a conductivity opposite that of the substrate. Thus, at least a portion of the amorphous semiconductor layer forms a heterojunction with the substrate. In the present exemplary embodiment, wherein the substrate 10 is an n-type silicon substrate, the graded amorphous layer 12 is an intrinsic-to-p-type graded amorphous silicon, for instance. That is, the layer 12 is graded, such that the region 16 is intrinsic and the region 18 is doped with a p-type dopant.

In many embodiments, a transparent conductive coating 20 is disposed on the amorphous layer 12, on the light-receiving side of the photovoltaic device. Coating 20 functions as the front electrode of the device. The transparent conductive coating 20 can comprise a variety of materials, such as metal oxides. Non-limiting examples include zinc oxide (ZnO) and aluminum doped zinc oxide. Coating 20 can be formed on top of the amorphous layer 12 by various conventional techniques, such as sputtering or evaporation. Its thickness will depend on various factors, such as the anti-reflective (AR) characteristics of the material. Usually, transparent conductive coating 20 will have a thickness in the range of about 200 Angstroms to about 1000 Angstroms.

As will be appreciated, in many conventional photovoltaic devices, conductive contacts are generally disposed and patterned on top of the transparent conductive coating 20 to carry electric current generated by the photovoltaic device to a desired location. However, as previously described, metal contacts on the front surface of the photovoltaic device disadvantageously shade the underlying semiconductor material, thereby reducing the efficiency of the photovoltaic device. As will be described further below, in accordance with embodiments of the present invention, the contacts to the front electrode (i.e., transparent conductive coating 20) are instead formed on the backside of the photovoltaic device (i.e., the side of the photovoltaic device that does not receive the incident light radiation). The contacts are electrically coupled to the front electrode through a conductive material disposed in contact vias formed through the substrate. Advantageously, by moving the conductive contacts from the front side to the backside of the photovoltaic device, the shadowing effect can be eliminated, thereby improving the efficiency of the photovoltaic device, as will be described further below.

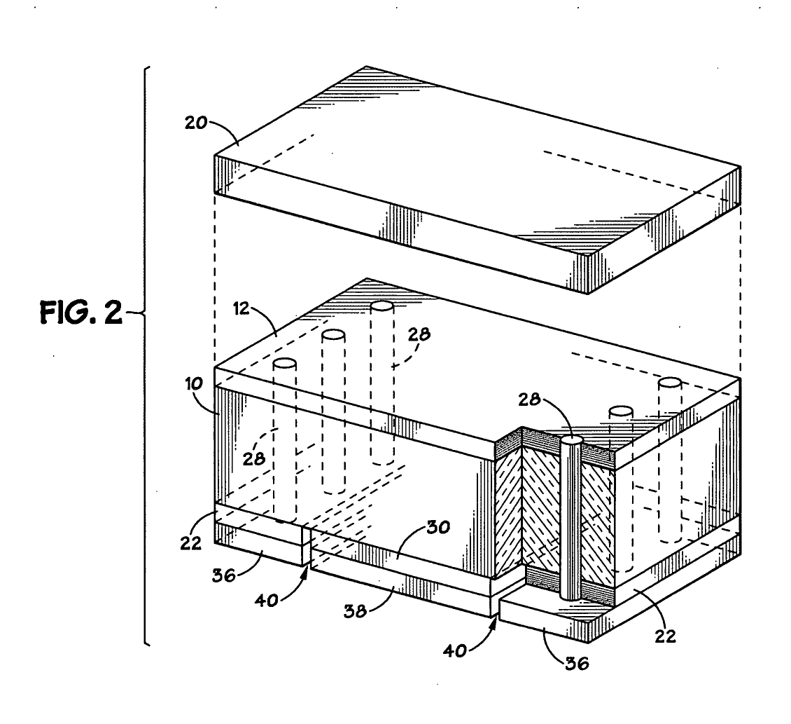

As previously described, the front and back surfaces of the semiconductor substrate may optionally be textured to enhance light trapping. To further enhance charge-carrier collection, another compositionally graded amorphous layer 22 is formed over portions of the backside of the substrate 10. In the present exemplary embodiment, the compositionally graded amorphous layer 22 is substantially the same as the graded amorphous layer 12. As with the layer 12, the graded amorphous layer 22 includes a substantially intrinsic portion 24 and a substantially conductive portion 26. In the present exemplary embodiment and similar to the amorphous layer 12, the layer 22 may comprise an intrinsic-to-p-type grading. As previously described, by providing a graded amorphous layer 22 disposed on the substrate 10, certain advantages over a traditional non-graded heterojunction-forming layer may be achieved. As will be described further below with respect to FIG. 2, the compositionally graded amorphous layer 22 may be patterned along with the overlying front contact layer to form an interdigitated contact structure on the backside of the substrate 10.

The electrical interconnection between the front conductive layer 20 and the front side contacts that will be disposed on the backside of the photovoltaic device (front contact 36 described below), is accomplished by a highly conductive material 28 within holes or vias formed through the substrate 10. The vias may be formed by any one of a number of techniques, including etching (e.g. wet chemical etching or plasma etching), mechanical abrasion or drilling using lasers or ultrasonic techniques. Laser ablation is a fast process meeting the overall targets of solar cell processing and may be preferential in many applications. For instance, a Q-switched Nd: YAG laser beam may be used to form the vias. The vias may be formed from the backside of the structure, through the graded layer 22, the substrate 10 and the graded layer 12 to expose the underlying conductive coating 20. Once the holes or vias are formed through the graded layer 22, the substrate 10 and the graded layer 12, the electrical interconnection between front and rear side contact is accomplished by disposing a highly conductive material 28, such as copper (Cu), within the holes.

The photovoltaic device of FIG. 1 also includes a graded amorphous layer 30. As in the case of layer 12, the layer 30 is graded, to provide a substantially intrinsic portion 32, and a substantially conductive portion 34. Unlike the graded amorphous layers 12 and 22, the amorphous layer 30 forms a homojunction with the substrate 10. In the present exemplary embodiment, wherein the substrate 10 is an n-type substrate, the amorphous layer 30 is an intrinsic-to-n-type graded amorphous silicon, for instance. That is, the layer 30 is graded, such that the region 32 is intrinsic and the region 34 is doped with an n-type dopant. Thus, passivation at the interface between the substrate and layer 30 can be achieved, without the drawbacks associated with the use of separate, discrete intrinsic layers and conductive layers. As will be appreciated, the electrons generated by the incident light radiation can travel through the substrate 10 to the layer 30 for charge collection.

The particular gradient (grading pattern) of amorphous layer 30 may differ from the gradient of layer 12, depending in part on the electrical requirements of the device. Grading can be undertaken with the same equipment used for the front side. The thickness of amorphous layer 30 does not have to be identical to the thickness of layer 12, but is also preferably less than or equal to about 250 Angstroms. In some specific embodiments, graded layer 30 has a thickness in the range of about 30 Angstroms to about 180 Angstroms. Again, those skilled in the art will be able to determine the optimum thickness for a given semiconductor structure.

To provide connection and routing of the electrical current generated by the photovoltaic reactions within the device, front contacts 36 and back contacts 38 may be formed on the backside of the device. The front contacts 36, in conjunction with the TCO layer 20 serve as one conducting electrode, while the back contacts 38 serves as the other (counter) conducting electrode. The electrodes 36 and 38 are generally metal and can be formed of a variety of conductive materials, such as silver (Ag), aluminum (Al), copper (Cu), molybdenum (Mo), tungsten (W), and various combinations thereof. Moreover, their shape, size, and number can vary, depending in part on the layer structure and electrical configuration of the device. The metal contacts can be formed by various techniques, e.g., screen printing; vacuum evaporation (sometimes using a mask), pneumatic dispensing, or direct-write techniques such as ink jet printing. Typically, the thickness of the contacts 36 and 38 is in the range of about 500 Angstroms to about 5000 Angstroms.

As will be appreciated, the front contacts 36 are electrically isolated from the back contacts 38. In the present exemplary embodiment, isolation trenches 40 are formed such that each of the front contacts 36 on the back surface of the device are electrically isolated from each the back contacts 38 on the back surface of the device. In accordance with one exemplary embodiment, a continuous layer of conductive material (e.g., metal) may be disposed on the back surface of the graded amorphous layers 22 and 30, by a conventional technique. Once the contact metal has been disposed, trenches 40 may be formed through the metal layer and the graded amorphous layers 22 and 30 to isolate the front and back contacts 36 and 38.

As described above, in order to provide electrical isolation of the front and back contacts 36 and 38, isolation trenches 40 are formed through the contact metal and the backside amorphous layers 22 and 30. The formation of the isolation trenches provides an interdigitated pattern of the contacts 36 and 38 on the backside of the device. That is to say, the front contacts 36 and back contacts 38 are formed such that they are arranged in alternating rows, separated by the isolation trenches 40, as best illustrated in FIG. 2. FIG. 2 illustrates a partially exploded plan view of the structure illustrated in FIG. 1. As illustrated in FIG. 2, the front contacts 36 are arranged in an alternating or interdigitated manner with the back contacts 38. In the view illustrated in FIG. 2, the conductive coating 20 has been exploded such that the conductive material 28 which provides a highly conductive, electrical connection between the conductive coating 20 and the front contacts 36 is visible. As previously described, a number of contact vias may be formed through the substrate 10 to provide a conductive path from the front side of the device to the front contacts 36 located on the backside of the device.

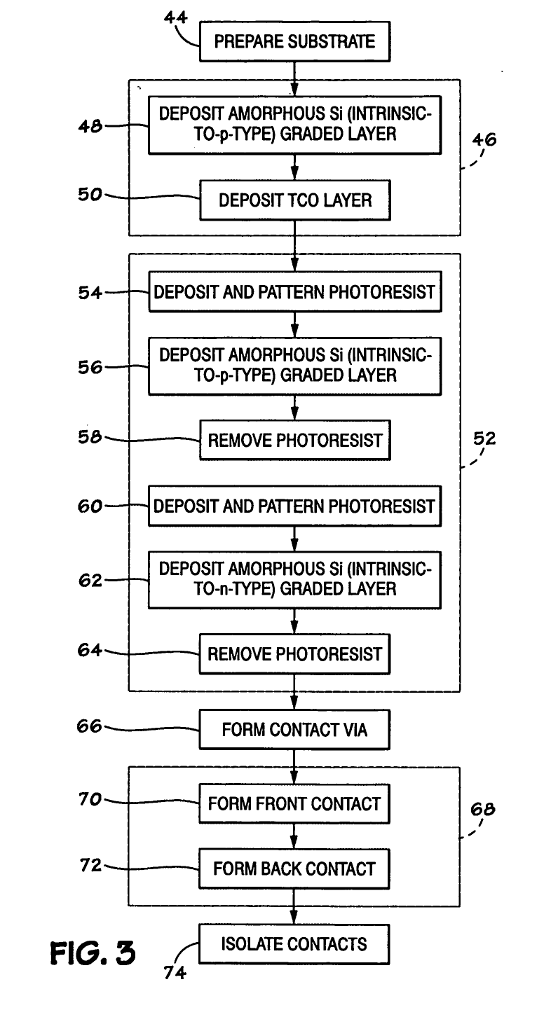

FIG. 3 is a flow chart providing a non-limiting illustration of the fabrication process 42 of a photovoltaic device according to embodiments of the present invention described above with respect to FIGS. 1 and 2. For simplicity, the reference numerals relating to the elements previously described will be omitted in describing the process flow. Those skilled in the art will appreciate the relationship with the exemplary process described with reference to FIG. 3 and the structural elements illustrated in FIGS. 1 and 2.

First, a monocrystalline or polycrystalline semiconductor substrate of one conductivity type (e.g., n-type) may be placed into a plasma reaction chamber (e.g., a plasma enhanced chemical vapor deposition system) to clean and smooth the surfaces of the substrate for processing, as indicated in block 44. As previously described, the front and back surfaces of the semiconductor substrate may optionally be textured to enhance light trapping. A vacuum pump removes atmospheric gases from the chamber. The substrate to be processed is preheated to about 120 to about 240° C. During the preparation step (block 44), a hydrogen plasma surface preparation step is performed prior to the deposition of the first compositionally graded layer. Hydrogen (H₂) is introduced into the chamber at a flow rate of about 50 to about 500 sccm (standard cubic centimeters per minute). A throttle valve is used to maintain a constant processing pressure in the range of about 200 mTorr to about 800 mTorr. Alternating frequency input power with a power density in the range of about 6 mW/cm² to about 50 mW/cm² range is used to ignite and maintain the plasma. Applied input power can be from about 100 kHz to about 2.45 GHz. Hydrogen plasma surface preparation time is about 1 to about 60 seconds. As will be appreciated, the hydrogen plasma substrate preparation (block 44) is optional and may be omitted. Further, the substrate preparation (block 44) may include other cleaning steps, as well. For instance, prior to insertion into the plasma chamber, the substrate may receive a wet chemical cleaning step.

After preparation of the substrate, the front surface of the substrate is processed. The processing of the front surface of the substrate is generally indicated by block 46, which includes deposition of the graded amorphous silicon (block 48) and deposition of the TCO layer (block 50). More specifically, at the end of the hydrogen plasma preparation, silane (SiH₄) is introduced into the process chamber at a flow rate of about 10 sccm to about 60 sccm. This will initiate the deposition of the compositionally-graded single amorphous semiconductor layer, as indicated in block 48. Because no dopant precursors are included in the plasma, the composition of the amorphous layer is initially intrinsic (undoped), thus serving to passivate the surface of the semiconductor substrate. As the deposition process progresses, a dopant precursor is subsequently added to the plasma mixture. Examples of dopant precursors are: B₂H₆, B(CH₃)₃, and PH₃. These may be in pure form or diluted with a carrier gas such as argon, hydrogen or helium. The flow rate of the precursor is increased over the course of the compositionally-graded layer deposition. This forms a gradient in the doping concentration through the single layer. At the conclusion of the graded layer deposition process, concentrations of dopant precursor in the plasma are such that substantially doped amorphous semiconductor properties are achieved.

As previously described, in the present exemplary embodiment, an n-type monocrystalline silicon wafer is used as the substrate. After the hydrogen plasma surface preparation (which is optional), the compositionally-graded amorphous layer deposition is initiated. A mixture of pure hydrogen and silane may be used initially to form intrinsic (undoped) material properties that serve to passivate the substrate surface. Subsequently, a boron-containing precursor is incrementally introduced to the plasma. Since boron acts as a p-type dopant, the amorphous material begins to take on p-type electrical properties. This process proceeds with increasing boron-containing precursor flows until substantially conductive material properties are achieved. As a result, a compositionally-graded layer comprising a boron concentration that continuously varies over its thickness is obtained. The thickness of the graded layer is optimally less than or equal to about 250 Angstroms. This the graded amorphous layer is an intrinsic-to-p-type graded amorphous silicon and will form part of the front structure of the compositionally-graded device.

Next, a transparent conductive oxide (TCO) coating is deposited on the front side of the compositionally-graded layer, in order to form the conductive front electrode, as indicated in block 50. This coating may be, for example, zinc oxide (ZnO) or aluminum doped zinc oxide. The TCO properties, including thickness, can be selected such that these layers act as antireflective (AR) coatings.

Next, the backside of the substrate is processed, as generally indicated by block 52, which includes a number of steps. As previously described, the backside of the substrate will include interdigitated contacts, wherein some of the interdigitated contacts are coupled to the front electrode (TCO layer). Each of the contacts includes a graded amorphous layer between the conductive contact and the substrate, wherin the graded amorphous layer is also interdigitated. Because the amorphous layers below the contacts will have different doping properties, they are fabricated in separate steps.

To facilitate the patterning of the amorphous silicon layers, standard photolithographic techniques may be employed. For instance a photoresist may be deposited and patterned to correlate with the growth of the first graded layer on the backside of the substrate, as indicated in block 54. Those skilled in the art will appreciate the deposition and patterning steps. Next, the growth of the compositionally-graded amorphous layer is initiated in the patterned areas, as indicated in block 56. As with the graded amorphous layer on the front side of the substrate, a mixture of pure hydrogen and silane may be used initially to form intrinsic (undoped) material properties that serve to passivate the substrate surface. Subsequently, a boron-containing precursor is incrementally introduced to the plasma. Since boron acts as a p-type dopant, the amorphous material begins to take on p-type electrical properties. This process proceeds with increasing boron-containing precursor flows until substantially conductive material properties are achieved. As a result, a compositionally-graded layer comprising a boron concentration that continuously varies over its thickness is obtained. The thickness of the graded layer is optimally less than or equal to about 250 Angstroms. This the graded amorphous layer is an intrinsic-to-p-type graded amorphous silicon and will provide the surface for the front contacts formed on the backside of the device. Once the amorphous graded layer is deposited, the photoresist employed to form the desired interdigitated pattern may be removed, as indicated in block 58.

A similar procedure is followed to passivate the interface with the substrate surface for the back contacts on the backside of the device to form a back surface field (BSF), as indicated in blocks 60, 62 and 64. The difference is that instead of a boron-containing precursor material, a phosphorous-containing precursor is used. Since phosphorous is an n-type dopant, the amorphous material begins to take on n-type electrical properties as the deposition progresses. At the conclusion of the compositionally-graded layer deposition, substantially conductive material properties are achieved. In this case, a compositionally-graded layer comprising a phosphorous concentration that continuously varies over its thickness is obtained. Again, the thickness of the compositionally graded layer is optimally less than or equal to about 250 Angstroms.

Next, the contact vias are formed through the substrate, as indicated in block 66. As previously described, the formation of the vias may be performed using a a Q switched Nd: YAG laser operating at 1064 nm is multi-mode. Once the contact vias are formed, a metal, such as copper (Cu) may be disposed therein, as previously described. Metallization of the contact vias may be accomplished by electroless plating, screen printing, or ink-jet printing, for example. “Electroless plating” refers to deposition techniques of metallic films by means of an autocatalytic chemical bath. In this heterogeneous catalytic electron transfer reaction, the electrons are transferred across an interface from a reducing agent to the metal ions. This reaction occurs on metal and semiconductor surfaces only (not on dielectrics). The chemical deposition of a metal from a metal salt solution is a redox reaction with both oxidation and reduction.

Once the graded layers and the conductive contacts have been formed, the front and back interdigitated contacts are formed on the backside of the structure, as generally indicated by block 68. In one embodiment, the front contacts are screen printed onto the intrinsic-to-p-type amorphous graded layer on the backside of the substrate, as indicated in block 70. The front contacts may be metal contacts (e.g., Al, Ag, and the like), for example. Next, the back contacts are screen printed onto the intrinsic-to-n-type amorphous graded layer on the backside of the substrate, as indicated by block 72. Finally, isolation trenches are formed to isolate the respective front and back contacts, as well as the respective graded layers thereunder, as indicated in block 74. The isolation trenches may be formed by conventional etching or laser techniques. Alternatively, a single step may be employed to deposit a continuous layer of metal on the backside of the structure. The formation of the trenches is then employed to provide separation of the front and back contacts.

Referring now to FIG. 4, an alternate embodiment of the semiconductor structure illustrated in FIG. 1 and described herein is provided. In this figure, elements similar or identical to those of FIG. 1 are not labeled or are provided with like reference numerals. Thus, the compositionally graded layer 12 is applied on the front surface of the substrate 10. The transparent conductive coating 20 is applied over the layer 12. However, in this embodiment, rather than applying a compositionally graded intrinsic-to-p-type amorphous layer to the backside, as in element 22 of FIG. 1, a simple intrinsic amorphous silicon layer 76 is applied in the contact region for the front contacts, instead. The thickness of the intrinsic amorphous silicon layer 76 may be in the range of approximately 20-60 Angstroms, for example. The layer 76 may be disposed using conventional techniques known by those skilled in the art, such as a chemical vapor deposition (CVD) process. As will be appreciated, the present exemplary embodiment may be desirable in certain applications. Though the proposed graded structure in the interdigitated devices (e.g., FIG. 1) has clear advantages over heterojunction devices formed by combining a crystalline semiconductor and an amorphous semiconductor, still there are energy barriers that prohibit the collection of charge carriers. This is compounded by high electrical resistances of amorphous layers, making it more difficult for the charge carriers to move smoothly resulting in loss at the interface. Metal insulator semiconductor (MIS) structures, such as the structure illustrated in FIG. 4, may advantageously overcome some of the problems, resulting in enhanced power conversion efficiency, as described in U.S. Pat. No. 5,401,366 (Noguchi et al), which is incorporated herein by reference.

The remaining elements and processing steps are similar to those previously described above with respect to FIGS. 1-3. Accordingly, after deposition of the layer 76, the graded layer 30 may be disposed, and the conductive contacts 28 may be formed through the substrate 10. Finally, the front and back contacts 36 and 38 may be disposed on the backside of the device and the isolation trenches 40 may be formed.

In each of the embodiments described herein, the front and back contacts are all located on the backside of the device to prevent shading losses associated with contacts being disposed on the front surface, wherein incident light rays may be blocked by contacts located on the front surface. Advantageously, by forming the front and back contacts on the backside of the device provides a more efficient device.

In each of the embodiments described herein, the graded layer eliminates at least one interface between discrete multilayers, i.e., interfaces where charge carrier-recombination can occur, as discussed previously. Grading of the dopant concentration through a single layer is thought to provide a continuous variation of localized states in the energy band gap for the particular device, thereby eliminating abrupt band-bending. Moreover, the graded layer can also result in processing advantages during fabrication of the devices, as mentioned previously. For example, interruptions between deposition steps are minimized, so that there is less of an opportunity for the entry of contaminants.

The semiconductor structure described above is sometimes referred to as a “solar cell device”. One or more of these devices can be incorporated into the form of a solar module. For example, a number of the solar cells can be electrically connected to each other, in series or in parallel, to form the module. (Those of ordinary skill in the art are familiar with details regarding the electrical connections, etc). Such a module is capable of much greater energy output than the individual solar cell devices.

Non-limiting examples of solar modules are described in various references, e.g., U.S. Pat. No. 6,667,434 (Morizane et al), which is incorporated herein by reference. The modules can be formed by various techniques. For example, a number of solar cell devices can be sandwiched between glass layers, or between a glass layer and a transparent resin sheet, e.g., those made from EVA (ethylene vinyl acetate). Thus, according to some embodiments of this invention, solar modules contain at least one solar cell device which itself comprises a compositionally-graded amorphous layer adjacent a semiconductor substrate, as described previously. The use of the graded layers can improve device properties like photoelectric conversion efficiency, etc., and thereby improve the overall performance of the solar module.

In general, those skilled in the art are familiar with many other details regarding the primary components of the solar modules, e.g., the various substrate materials, backing materials, and module frames. Other details and considerations are also well-known, e.g., wire connections in and out of the module (for example, those leading to an electrical inverter); as well as various module encapsulation techniques.

While preferred embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the claimed inventive concept. All of the patents, patent applications (including provisional applications), articles, and texts which are mentioned above are incorporated herein by reference.

What is claimed:

1. A semiconductor structure, comprising:
a semiconductor substrate, wherein the substrate comprises a front side configured to receive incident light radiation, and a backside;
an amorphous semiconductor layer disposed on the front side of the semiconductor substrate, wherein the amorphous semiconductor layer is compositionally graded through its depth, from substantially intrinsic at the interface with the substrate, to substantially conductive at the opposite side;
a plurality of front contacts disposed on the backside of the substrate; and
a plurality of vias formed through the substrate, wherein each of the plurality of vias are filled with a conductive material configured to electrically couple the amorphous semiconductor layer to one of the plurality of front contacts.

2. The semiconductor structure of claim 1, wherein the substrate is monocrystalline or polycrystalline and is n-type or p-type.

3. The semiconductor structure of claim 2, wherein the amorphous semiconductor layer has a thickness of less than about 250 Angstroms.

4. The semiconductor structure of claim 2, wherein the amorphous semiconductor layer has a thickness in the range of about 30 Angstroms to about 180 Angstroms.

5. The semiconductor structure of claim 1, wherein the amorphous semiconductor layer comprises n-type or p-type impurities which provide a selected conductivity.

6. The semiconductor structure of claim 1, wherein a conductivity type of the amorphous semiconductor layer is opposite a conductivity type of the substrate.

7. The semiconductor structure of claim 1, wherein at least a portion of the amorphous semiconductor layer forms a heterojunction with the substrate.

8. The semiconductor structure of claim 1, wherein the concentration of impurities at the interface with the substrate is substantially zero and the concentration of impurities at the opposite side is in the range of about 1×10¹⁶ cm⁻³ to about 1×10²¹ cm⁻³.

9. The semiconductor structure of claim 1, wherein the plurality of front contacts comprises a metal.

10. The semiconductor structure of claim 1, further comprising an amorphous semiconductor layer disposed on the backside of the semiconductor substrate between the substrate and the front side contacts.

11. The semiconductor structure of claim 11, wherein the amorphous semiconductor layer is compositionally graded through its depth, from substantially intrinsic at the interface with the substrate, to substantially conductive at the opposite side.

12. The semiconductor structure of claim 1, further comprising a plurality of back contacts disposed on the backside of the substrate and being interdigitated with the plurality of front contacts.

13. The semiconductor structure of claim 12, further comprising an amorphous semiconductor layer disposed on the backside of the semiconductor substrate between the substrate and the front side contacts, wherein the amorphous semiconductor layer is compositionally graded through its depth, from substantially intrinsic at the interface with the substrate, to substantially conductive at the opposite side, and wherein a conductivity type of the amorphous semiconductor layer on the backside comprises the same conductivity type as that of the substrate.

14. The semiconductor structure of claim 1, further comprising a transparent electrode layer disposed on the amorphous semiconductor layer.

15. A semiconductor structure, comprising:
a semiconductor substrate comprising a front side configured to receive incident light radiation, and a backside;
a first amorphous semiconductor layer disposed on the front side of the semiconductor substrate, wherein the first amorphous semiconductor layer is compositionally graded through its depth, from substantially intrinsic at the interface with the substrate, to substantially conductive at the opposite side;
a transparent electrode layer disposed on the first amorphous semiconductor layer;
a second amorphous semiconductor layer disposed on a first plurality of areas on the back side of the semiconductor substrate;
a plurality of front contacts disposed on the second amorphous semiconductor layer;
a plurality of vias formed through the substrate, wherein the plurality of vias are filled with a conductive material configured to electrically couple the transparent electrode layer to one of the plurality of front contacts;
a third amorphous semiconductor layer disposed on a second plurality of areas on the back side of the semiconductor substrate, wherein the third amorphous semiconductor layer is compositionally graded through its depth, from substantially intrinsic at the interface with the substrate, to substantially conductive at the opposite side; and
a plurality of back contacts disposed on the third amorphous semiconductor layer.

16. The semiconductor structure of claim 15, wherein the second amorphous semiconductor layer is compositionally graded through its depth, from substantially intrinsic at the interface with the substrate, to substantially conductive at the opposite side.

17. The semiconductor structure of claim 15, wherein the substrate has a first conductivity type, and wherein a conductivity type of the first amorphous semiconductor layer comprises a second conductivity type, opposite the first conductivity type, and wherein the third amorphous semiconductor layer comprises the first conductivity type.

18. The semiconductor structure of claim 15, wherein the plurality of front contacts are interdigitated with the plurality of back contacts.

19. A method for making a photovoltaic device, comprising:
disposing a first amorphous semiconductor layer on a front side of a semiconductor substrate, wherein the first amorphous semiconductor layer is compositionally graded through its depth, from substantially intrinsic at the interface with the substrate, to substantially conductive at the opposite side;
disposing a second amorphous semiconductor layer on a first plurality of areas on a backside of the semiconductor substrate;
disposing a third amorphous semiconductor layer on a second plurality of areas on the backside of the semiconductor substrate, wherein the third amorphous semiconductor layer is compositionally graded through its depth, from substantially intrinsic at the interface with the substrate, to substantially conductive at the opposite side;
forming a plurality of vias through the substrate;
filling each of the plurality of vias with a conductive material;
forming a plurality of front contacts on the second amorphous semiconductor layer; and
forming a plurality of back contacts on the third amorphous semiconductor layer.

20. The method of claim 19, wherein disposing the first amorphous semiconductor layer and disposing the third amorphous semiconductor layer each comprise continuously depositing semiconductor material and a dopant over the substrate, while altering the concentration of the dopant, so that the semiconductor layer becomes compositionally-graded through its depth from substantially intrinsic at the interface with the substrate, to substantially conductive at the opposite side of the semiconductor layer.

21. The method of claim 20, wherein disposing the second amorphous semiconductor layer comprises continuously depositing semiconductor material and a dopant over the substrate, while altering the concentration of the dopant, so that the semiconductor layer becomes compositionally-graded through its depth from substantially intrinsic at the interface with the substrate, to substantially conductive at the opposite side of the semiconductor layer.

22. The method of claim 19, wherein disposing the first, second and third amorphous semiconductor layers each comprise disposing by a plasma deposition process.

23. The method of claim 19, wherein forming the plurality of vias comprises laser drilling through the substrate.

24. The method of claim 19, wherein forming the plurality of front contacts and forming the plurality of back contacts comprises disposing the plurality of front contacts such that the front contacts are interdigitated with respect to the back contacts.

25. The method of claim 19, further comprising depositing a transparent electrode layer over the surface of the first amorphous semiconductor layer.
